(19) United States
(12) Patent Application Publication
(10) Pub. No.: US 2025/0216716 A1
(43) Pub. Date: Jul. 3, 2025

(54) DISPLAY PANEL AND PERSONAL IMMERSIVE DEVICE INCLUDING THE SAME

(71) Applicant: LG Display Co., Ltd., Seoul (KR)

(72) Inventors: Hye Jeong PARK, Paju-si (KR); Byung Gwan HYUN, Paju-si (KR)

(21) Appl. No.: 18/958,974

(22) Filed: Nov. 25, 2024

(30) Foreign Application Priority Data
Dec. 28, 2023 (KR) 10-2023-0195347

(51) Int. Cl. G02F 1/1335; G02F 1/1337; G02F 1/137

(52) U.S. Cl. CPC G02F 1/133553; G02F 1/133514; G02F 1/133526; G02F 1/1337; G02F 1/137; G02F 2201/343; G02F 2203/02

(57) ABSTRACT

An embodiment discloses a display panel including a substrate, a plurality of pixels including a first sub-pixel, a second sub-pixel, and a third sub-pixel disposed on the substrate, and a reflective layer including a first reflective portion disposed on the first sub-pixel, a second reflective portion disposed on the second sub-pixel, and a third reflective portion disposed on the third sub-pixel, wherein thicknesses of the first reflective portion to the third reflective portion are different, and a display device including the same.

### CROSS-REFERENCE TO RELATED APPLICATION

This application claims priority to and the benefit of Korean Patent Application No. 10-2023-0195347, filed on Dec. 28, 2023, the disclosure of which is incorporated herein by reference in its entirety.

### BACKGROUND

### Technical Field

The present specification relates to a display panel and a personal immersive device including the same.

### Description of the Related Art

Personal immersive devices are being developed in various types such as a head mounted display (HMD) device, a face mounted display (FMD) device, an eye glasses-type display (EGD) device, and the like. The personal immersive devices are classified as virtual reality (VR) devices and augmented reality (AR) devices.

Recently, the personal immersive devices are using polarization-based optical systems to reduce a distance between user's eyes and a display panel. However, the polarization-based optical systems have a problem in that only a portion of light is transmitted through a polarizer and thus a brightness is lowered.

### BRIEF SUMMARY

One embodiment of the present specification is directed to providing a display panel with an improved brightness and a personal immersive device including the same.

The technical problems of the present specification are not limited to the above-mentioned technical problems, and other technical problems which are not mentioned may be clearly understood by those skilled in the art from the following description.

A display panel according to one aspect of the present disclosure includes a substrate, a plurality of pixels including a first sub-pixel, a second sub-pixel, and a third sub-pixel disposed on the substrate, and a reflective layer including a first reflective portion disposed on the first sub-pixel, a second reflective portion disposed on the second sub-pixel, and a third reflective portion disposed on the third sub-pixel, wherein thicknesses of the first reflective portion to the third reflective portion are different.

The first reflective portion may be thicker than the second reflective portion, and the second reflective portion may be thicker than the third reflective portion.

The first reflective portion to the third reflective portion may include cholesteric liquid crystals, and pitches of the cholesteric liquid crystals included in the first reflective portion to the third reflective portion may be different.

The first reflective portion may selectively transmit and reflect red light corresponding to the pitch of the cholesteric liquid crystal, the second reflective portion may selectively transmit and reflect green light corresponding to the pitch of the cholesteric liquid crystal, and the third reflective portion may selectively transmit and reflect blue light corresponding to the pitch of the cholesteric liquid crystal.

The display panel may further include a color filter disposed between the plurality of pixels and the reflective layer, wherein the color filter may include a first filter disposed between the first sub-pixel and the first reflective portion, a second filter disposed between the second sub-pixel and the second reflective portion, and a third filter disposed between the third sub-pixel and the third reflective portion.

A thickness of the first filter may be smaller than a thickness of the second filter, and a thickness of the second filter may be smaller than a thickness of the third filter.

The display panel may further include a encapsulation layer disposed between the plurality of pixels and the reflective layer, wherein the encapsulation layer may include a first encapsulation portion disposed between the first sub-pixel and the first reflective portion, a second encapsulation portion disposed between the second sub-pixel and the second reflective portion, and a third encapsulation portion disposed between the third sub-pixel and the third reflective portion, a thickness of the second encapsulation portion may be greater than a thickness of the first encapsulation portion, and a thickness of the third encapsulation portion may be greater than a thickness of the second encapsulation portion.

The display panel may further include an alignment film disposed between the reflective layer and the color filter.

The alignment film may include first regions disposed on the first filter to the third filter, and second regions disposed on a side surface of the second filter and a side surface of the third filter.

The first sub-pixel, the second sub-pixel, and the third sub-pixel may emit light of different colors.

The first sub-pixel, the second sub-pixel, and the third sub-pixel may emit light of the same color.

The display panel may further include a light concentrating layer disposed between the plurality of pixels and the reflective layer, wherein the light concentrating layer may include high refractive index layers disposed on the first sub-pixel to the third sub-pixel and a low refractive index layer disposed on the high refractive index layers.

Each of the first sub-pixel, the second sub-pixel, and the third sub-pixel may include a first electrode, a light-emitting element disposed on the first electrode, and a second electrode disposed on the light-emitting element.

The light-emitting element may include an organic light-emitting element or an inorganic light-emitting element.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a view schematically illustrating a personal immersive device;

FIG. 2 is a view illustrating a display device according to one embodiment of the present disclosure;

FIGS. 3 and 4 are views illustrating that the size of the personal immersive device varies depending on a lens type;

FIG. 5 is a view illustrating a display panel structure for improving a lowered brightness;

FIG. 6 is a view illustrating a display panel according to a first embodiment of the present disclosure;

FIG. 7 is a view illustrating a process in which a brightness is improved by a cholesteric liquid crystal layer;

FIG. 8 is a view illustrating a mismatch between a wavelength of light emitted from a color filter and a transmission wavelength of a reflective layer;

FIG. 9 is a view illustrating a mismatch between a wavelength of light emitted from a light-emitting layer and the transmission wavelength of the reflective layer;

FIG. 10 is a view illustrating a display panel according to a second embodiment of the present disclosure;

FIG. 11 is a view illustrating a display panel according to a third embodiment of the present disclosure;

FIG. 12 is a view illustrating a display panel according to a fourth embodiment of the present disclosure;

FIG. 13 is a view illustrating a display panel according to a fifth embodiment of the present disclosure;

FIG. 14 is a view illustrating a display panel according to a sixth embodiment of the present disclosure;

FIG. 15 is a view illustrating a display panel according to a seventh embodiment of the present disclosure;

FIG. 16 is a view illustrating a display panel according to an eighth embodiment of the present disclosure;

FIG. 17 is a view illustrating a display panel according to a ninth embodiment of the present disclosure;

FIGS. 18A to 18E are views illustrating a process of manufacturing a display panel according to one embodiment of the present disclosure;

FIG. 19 is a view illustrating a display panel according to a tenth embodiment of the present disclosure;

FIGS. 20A to 20C are views illustrating a process of manufacturing a display panel according to one embodiment of the present disclosure; and

FIG. 21 is an exploded perspective view illustrating a personal immersive device according to one embodiment of the present disclosure.

### DETAILED DESCRIPTION

Advantages and features of the present disclosure, and methods of achieving them will become apparent with reference to the following embodiments, which are described in detail, in conjunction with the accompanying drawings. However, the present disclosure is not limited to the embodiments to be described below and may be implemented in various different forms, the embodiments are only provided to completely disclose the present specification and completely convey the scope of the present disclosure to those skilled in the art, and the claims are not limited by the disclosure.

Since the shapes, sizes, proportions, angles, numbers, and the like disclosed in the drawings for describing the embodiments of the present disclosure are only exemplary, the present disclosure is not limited to the items shown in the drawings. The same reference numerals refer to the same components throughout the specification. Further, in describing present disclosure, when it is determined that a detailed description of related known technology may unnecessarily obscure the gist of the present disclosure, the detailed description thereof will be omitted.

When “providing,” “including,” “having,” “consisting of,” and the like mentioned in the present specification are used, other parts may be added unless “only” is used. A case where a component is expressed in a singular form includes a plural form unless explicitly stated otherwise.

In interpreting the components, it should be understood that an error range is included even when there is no separate explicit description.

When positional relationships and interconnection relationships between two components such as “on,” “at an upper portion,” “at a lower portion,” “next to,” “connect or couple,” “crossing or intersecting,” and the like are described, one or more other components may be interposed between the two components unless “immediately” or “directly” is mentioned.

A case where temporal relationships are described as “after,” “in succession to,” “and then,” “before,” and the like may not be continuous on a time axis unless “immediately” or “directly” is used.

In the description of the embodiments, although first, second, and the like are used to describe various components, these components are not limited by these terms. These terms are only used to distinguish one component from another component. Accordingly, a first component to be mentioned below may also be a second component within the technical spirit of the present specification.

The same reference numerals refer to the same components throughout the specification.

Features of various embodiments may be partially or entirely coupled to or combined with each other, and technically, various types of interconnections and driving are possible, and the embodiments may be implemented independently of each other or may be implemented together in a related relationship.

Hereinafter, various embodiments of the present disclosure will be described in detail with reference to the accompanying drawings.

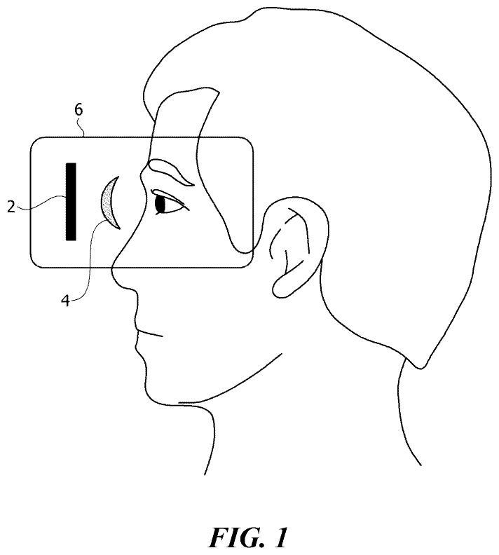

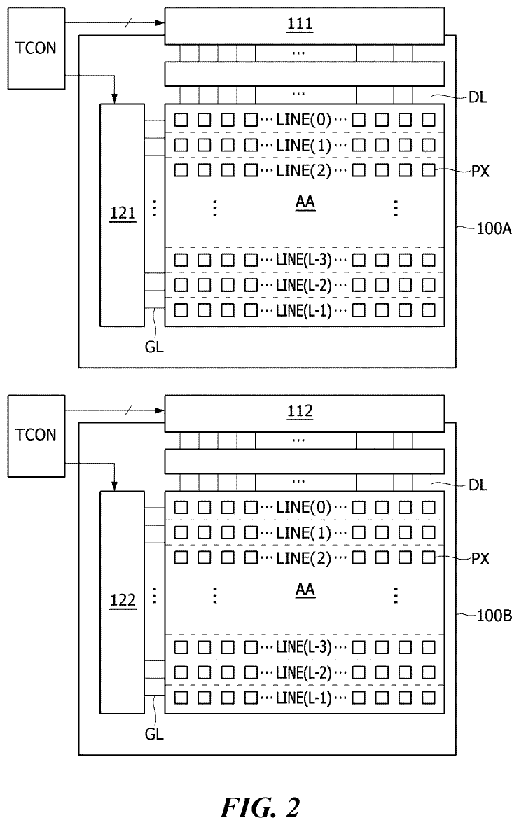

FIG. 1 is a view schematically illustrating a personal immersive device. FIG. 2 is a view illustrating a display device according to one embodiment of the present disclosure.

Referring to FIGS. 1 and 2, the personal immersive device may include a main body 6 worn on a user's head, and a display device 2 and a lens 4 accommodated in the main body 6, and the display device may include a first display panel 100A on which a left-eye image is displayed, and a second display panel 100B on which a right-eye image is displayed.

The display panels 100A and 100B include data lines DL, gate lines GL, and pixels PX. Screens of the display panels 100A and 100B include pixel arrays on which images are displayed. The pixel array includes pixel lines L1 to Ln sequentially scanned by a scan pulse shifted in a scanning direction so that pixel data is written.

A display panel driver may include data drivers 111 and 112, gate drivers 121 and 122, a controller 130, and the like. The data drivers 111 and 112 and the gate drivers 121 and 122 may be separated for each of display panels 100A and 100B, and the controller 130 may be shared. The data drivers 111 and 112 convert pixel data input from the controller 130 to a voltage or current and supply data signals to pixels. The gate drivers 121 and 122 sequentially output scan pulses synchronized with the data signals output from the data drivers 111 and 112 under control of the controller 130.

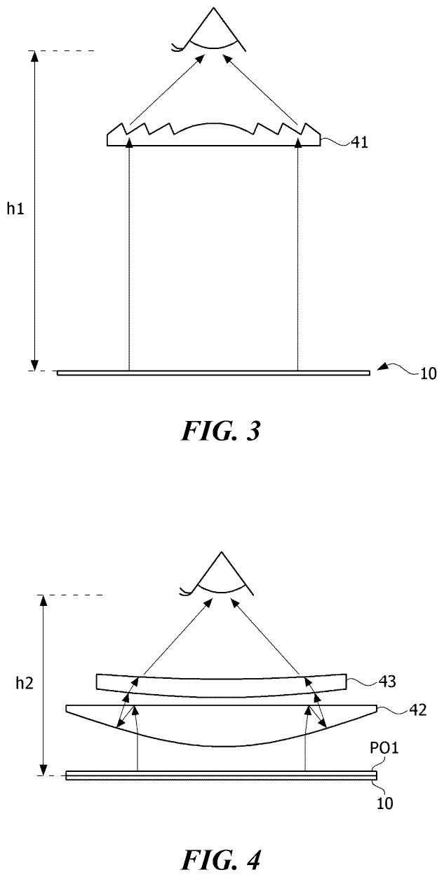

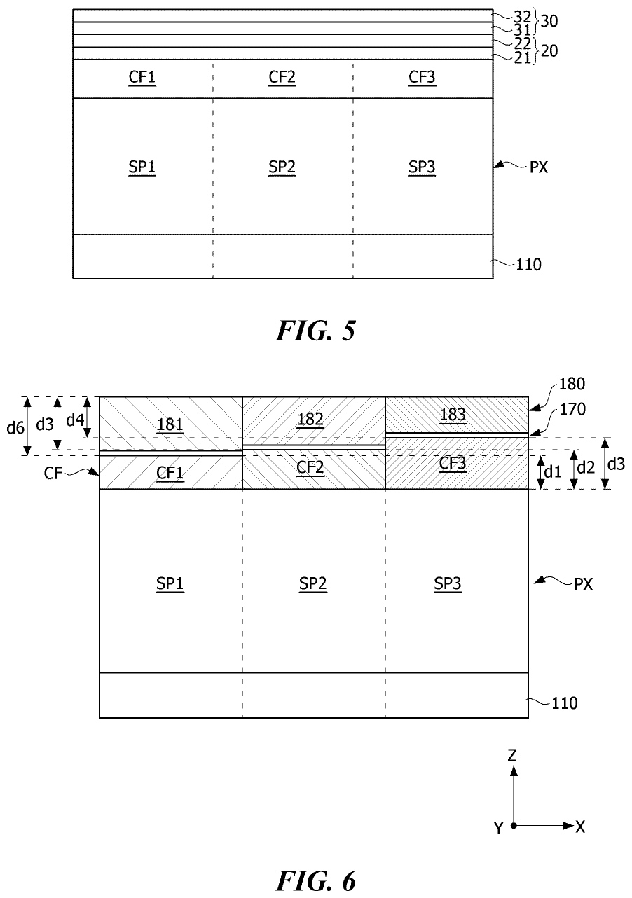

FIGS. 3 and 4 are views illustrating that the size of the personal immersive device varies depending on a lens type. FIG. 5 is a view illustrating a display panel structure for improving a lowered brightness.

Referring to FIG. 3, when the personal immersive device is implemented using the Fresnel lens 41 on a display device 10, a first distance h1 is required to focus a screen of the display device on the retinas of the eyes. On the other hand, when a plurality of polarization-based lenses 42 and 43 are used as shown in FIG. 4, the retinas of the eyes may be focused at a second distance h2 shorter than the first distance h1. Accordingly, for miniaturization, it is preferable to use a combined structure of a polarizer PO1 and the lenses 42 and 43 in a virtual reality (VR) device or an augmented reality (AR) device, but this polarization-based optical system uses only a portion of light passing through the polarizer, and thus has a disadvantage of a low brightness.

Referring to FIG. 5, the display panel may reduce a focal length by installing a circular polarizer 30 composed a linear polarizer 31 and a quarter wavelength plate 32 on color filters CF1, CF2, and CF3, but since only some of circularly polarized light is transmitted by the circular polarizer 30, a brightness is lowered. Accordingly, in order to improve the brightness, a light concentrating layer 20 in which a high refractive index layer 21 and a low refractive index layer 22 are disposed needs to be additionally disposed to compensate for the brightness. However, when the light concentrating layer 20 is formed, brightness uniformity due to process dispersion may occur and moire may occur.

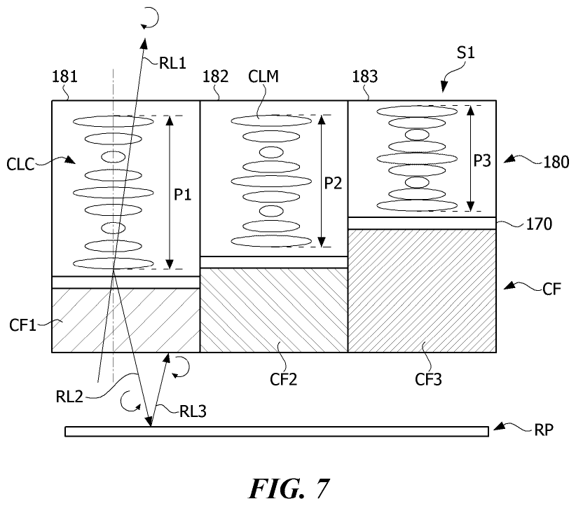

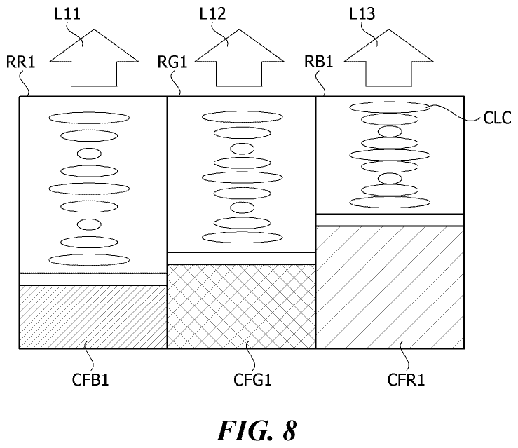

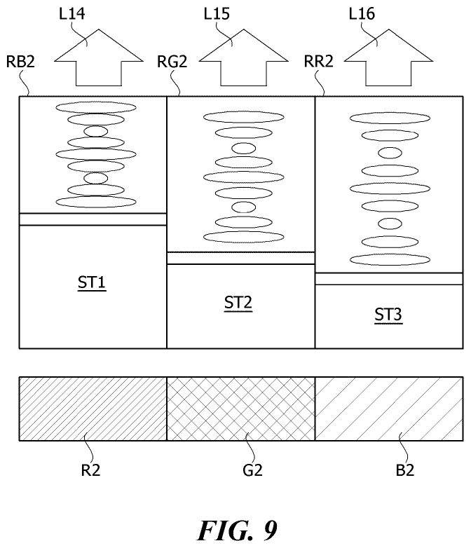

FIG. 6 is a view illustrating a display panel according to a first embodiment of the present disclosure. FIG. 7 is a view illustrating a process in which a brightness is improved by a cholesteric liquid crystal layer. FIG. 8 is a view illustrating a mismatch between a wavelength of light emitted from a color filter and a transmission wavelength of a reflective layer. FIG. 9 is a view illustrating a mismatch between a wavelength of light emitted from a light-emitting layer and the transmission wavelength of the reflective layer.

Referring to FIG. 6, the display panel according to the embodiment may include a substrate 110, a pixel PX including a plurality of sub-pixels SP1, SP2, and SP3 disposed on the substrate 110, and a reflective layer 180 disposed on the plurality of sub-pixels SP1, SP2, and SP3.

The substrate 110 may be manufactured based on glass, plastic, and a silicon wafer. The substrate 110 may be interpreted as a backplane.

A structure of a plurality of pixels PX is not specifically limited. For example, the plurality of pixels PX may include organic light-emitting diode (OLED) elements or inorganic light-emitting diode (LED) elements. The inorganic LED elements may serve as sub-pixels as each of small micro-sized LEDs emits light.

The plurality of pixels may include a first sub-pixel SP1, a second sub-pixel SP2, and a third sub-pixel SP3 to implement colors. The first sub-pixel SP1, the second sub-pixel SP2, and the third sub-pixel SP3 may output light in different wavelength bands. For example, the first sub-pixel SP1 may output light in a red wavelength band, the second sub-pixel SP2 may output light in a green wavelength band, and the third sub-pixel SP3 may output light in a blue wavelength band. Each sub-pixel may include a light-emitting element layer and a circuit layer which drives the light-emitting element layer.

However, the present disclosure is not necessarily limited thereto, and the first sub-pixel SP1, the second sub-pixel SP2, and the third sub-pixel SP3 may all output light in the same wavelength band. For example, the first sub-pixel SP1, the second sub-pixel SP2, and the third sub-pixel SP3 may all output light in a white wavelength band. To this end, each of the sub-pixels SP1, SP2, and SP3 may have a structure in which a red light-emitting layer, a green light-emitting layer, and a blue light-emitting layer are stacked.

The color filter CF may be disposed on the plurality of sub-pixels SP1, SP2, and SP3. The color filter CF may include a first filter CF1 disposed on the first sub-pixel SP1, a second filter CF2 disposed on the second sub-pixel SP2, and a third filter CF3 disposed on the third sub-pixel SP3. According to the embodiment, a black matrix may not be disposed between the filters. However, the present disclosure is not necessarily limited thereto, and the black matrix may be disposed between the filters to prevent color mixing.

The first filter CF1 may be a red filter, the second filter CF2 may be a green filter, and the third filter CF3 may be a blue filter. Accordingly, light emitted from the first filter CF1 may be red light, light emitted from the second filter CF2 may be green light, and light emitted from the third filter CF3 may be blue light.

According to the embodiment, thicknesses of the first to third filters CF1, CF2, and CF3 may be different. For example, a thickness d1 of the first filter CF1 may be smaller than a thickness d2 of the second filter CF2, and the thickness d2 of the second filter CF2 may be smaller than a thickness d3 of the third filter CF3.

That is, the third filter CF3 may be manufactured to be the thickest and the first filter CF1 may be manufactured to be the thinnest. The first to third filters CF1, CF2, and CF3 may be manufactured with the same thickness and then the thickness may be adjusted through a separate etching process. Various semiconductor etching processes may be applied to the etching process. At this time, in the case of the thinnest first filter CF1, since the performance of the color filter may deteriorate, a dye concentration may be increased to improve the performance. Accordingly, the dye concentration in the first filter CF1 may be higher than dye concentrations in the second filter CF2 and the third filter CF3.

Referring to FIGS. 6 and 7, an alignment film 170 may be formed on the first to third filters CF1, CF2, and CF3. The alignment film 170 may be rubbed in one direction. Accordingly, an alignment angle of the liquid crystal formed on the alignment film 170 may be set according to an aligning direction.

The reflective layer 180 may include a first reflective portion 181 disposed on the first filter CF1, a second reflective portion 182 disposed on the second filter CF2, and a third reflective portion 183 disposed on the third filter CF3.

The reflective layer 180 may be manufactured with cholesteric liquid crystals CLC. The cholesteric liquid crystals CLC form a layered structure like a smectic liquid crystal, and long axes of cholesteric liquid crystal molecules (CLMs) are disposed in parallel like a nematic liquid crystal. The cholesteric liquid crystals CLC may form a helical structure because orientation of an array is constantly changed in a layer direction in which the cholesteric liquid crystal molecules (CLM) are placed, and may selectively reflect light of a wavelength corresponding to a pitch of a helix.

When the cholesteric liquid crystals are applied on the first to third filters CF1, CF2, and CF3 manufactured with different thicknesses, the first reflective portion 181 may be formed on the first filter CF1, the second reflective portion 182 may be formed on the second filter CF2, and the third reflective portion 183 may be formed on the third filter CF3.

Since the cholesteric liquid crystals are filled with predetermined thicknesses on the color filter CF, an upper surface S1 may be formed at the same height. Accordingly, the first reflective portion to the third reflective portions 181, 182, and 183 may be manufactured with different thicknesses. A thickness d6 of the first reflective portion 181 formed on the first filter CF1 which is disposed to be the lowest may be greater than a thickness d5 of the second reflective portion 182 formed on the second filter CF2, and the thickness d5 of the second reflective portion 182 may be greater than a thickness d4 of the third reflective portion 183.

As a result, in the first reflective portion 181 which is manufactured to be the thickest, the cholesteric liquid crystals may grow in a helical shape and have a pitch P1 which reflects light in the red wavelength band. Further, in the second reflective portion 182 which is manufactured with a thickness smaller than that of the first reflective portion 181, the cholesteric liquid crystals may grow in a helical shape and have a pitch P2 which reflects light in the green wavelength band. In addition, in the third reflective portion 183 manufactured with to be the smallest thickness, the cholesteric liquid crystals may grow in a helical shape and have a pitch P3 which reflects light in the blue wavelength band.

According to the embodiment, since the wavelength band in which the cholesteric liquid crystals perform reflection varies according to the pitches, the thickness of the reflective portion may be adjusted to reflect the light emitted from the color filter CF.

A pitch p of a helix may be a value obtained by dividing a wavelength λ of light reflected from the front by an average refractive index n of the liquid crystal molecules. The average refractive index n of the liquid crystal molecules may be 1.5 to 1.7 which is an average value of an abnormal refractive index ne and a normal refractive index no.

A wavelength of red light may be 600 nm to 780 nm, a wavelength of green light may be 500 nm to 580 nm, and a wavelength of blue light may be 430 nm to 500 nm.

Accordingly, when the wavelength of each color is divided by the average refractive index, the pitch p1 of a helix formed by the cholesteric liquid crystal molecules in the first reflective layer 181 may be 353 nm to 520 nm. The pitch p2 of a helix formed by the cholesteric liquid crystal molecules in the second reflective layer 182 may be 294 nm to 387 nm. The pitch p3 of a helix formed by the cholesteric liquid crystal molecules in the third reflective layer 183 may be 253 nm to 333 nm.

In a structure in which the cholesteric liquid crystal molecules rotate counterclockwise along a rotation axis which is a helical axis and form a helix, left-circularly polarized light may be reflected, and in a structure in which the cholesteric liquid crystal molecules rotate clockwise and form a helix, right-circularly polarized light may be reflected. Hereinafter, the cholesteric liquid crystal will be described as transmitting the right-circularly polarized light (clockwise) and reflecting the left-circularly polarized light (counterclockwise), but a polarization direction of reflecting light may vary depending on shapes of the helix.

The first reflective portion 181 may transmit right-circularly polarized light RL1 and reflect left-circularly polarized light RL2 among the red light emitted by the first filter CF1. Since the reflected light is reflected by a reflective plate RP or the substrate 110 disposed at a lower portion of the pixel, a polarization direction may be changed. For example, the left-circularly polarized light RL2 reflected by the cholesteric liquid crystals may be repeatedly reflected by the reflective plate RP or the substrate 110 and thus may be changed to the right-circularly polarized light RL3. Accordingly, the reflected red light may pass through the first filter CF1 and the first reflective portion 181 again and may be emitted to the outside.

The second reflective portion 182 may transmit right-circularly polarized light and reflect left-circularly polarized light among the green light emitted from the second filter CF2. Since the reflected light is reflected by the reflective plate RP or the substrate 110 disposed at the lower portion of the pixel, a polarization direction is changed and thus the reflected light may pass through the second reflective portion 182 thereafter.

The third reflective portion 183 may transmit right-circularly polarized light and reflect left-circularly polarized light among the blue light emitted from the third filter CF3. Since the reflected light reflected by the reflective plate RP or the substrate 110 disposed at the lower portion of the pixel, a polarization direction is changed and thus the reflected light may pass through the third reflective portion 183.

According to the embodiment, the reflective portion selectively transmits and reflects the circularly polarized light which is incident by the cholesteric liquid crystal layer, and thus may be applied to a polarization-based optical system. Accordingly, miniaturization of the personal immersive device is possible. Further, since an amount of light emitted from the display panel increases by recycling in which the polarization direction is changed through repetition of the reflection and transmission of light, the brightness may be improved without the need for a separate light concentrating layer.

FIG. 8 is a view illustrating a mismatch between the wavelength of the light emitted from the color filter and the transmission wavelength of the reflective layer. FIG. 9 is a view illustrating a mismatch between the wavelength of the light emitted from the light-emitting layer and the transmission wavelength of the reflective layer 180.

Referring to FIG. 8, a green filter CFG1 may be thicker than a blue filter CFB1, and a red filter CFR1 may be thicker than the green filter CFG1. Accordingly, since a first reflective portion RR1 formed on the blue filter CFB1 is formed to be relatively thicker, a pitch is elongated and thus the first reflective portion RR1 may reflect light in a red wavelength band. However, there is a problem in that light passing through the blue filter CFB1 is blue light and thus is not reflected by the first reflective portion RR1. Further, color mixing (L11 and L13) may occur in some regions.

Since a third reflective portion RB1 formed on the red filter CFR1 is formed to be relatively thinner, a pitch of the cholesteric liquid crystal is short and thus the third reflective portion RB1 may reflect light in a blue wavelength band. Accordingly, there is a problem in that the red light which passed through the red filter CFR1 is not reflected by the third reflective portion RB1. Further, color mixing (L14 and L15) may occur in some regions.

Accordingly, in order for the reflective layer to function as a polarizer which reflects some light and transmits some light, the red filter should be manufactured to be the thinnest so that the pitch of the cholesteric liquid crystal formed thereon may be elongated to reflect the red light. Further, the blue filter should be manufactured to be the thickest so that the pitch of the cholesteric liquid crystal formed thereon may be relatively shortened to reflect the blue light.

Referring to FIG. 9, when a step is formed in a separate optical layer, since a thickness of a first reflective portion RB2 is relatively small when a thickness of a first step portion ST1 disposed on the red sub-pixel R2 is great, the first reflective portion RB2 may have a pitch which reflects the blue light. Accordingly, there is a problem in that the light emitted from the red sub-pixel R2 is not reflected by the first reflective portion RB2.

On the other hand, since a thickness of the third reflective portion RR2 becomes relatively small when a thickness of a third step portion ST3 disposed on the blue sub-pixel B2 is great, the third reflective portion RR2 may have a pitch which reflects the red light. Accordingly, there is a problem in that the blue light emitted from the blue sub-pixel B2 is not reflected by the third reflective portion RR2.

Accordingly, the red filter should be formed to be the thinnest to form the cholesteric liquid crystal reflective layer which reflects the red light thereon, and the blue filter needs to be formed to be the thickest to form the cholesteric liquid crystal reflective layer which reflects the blue light thereon.

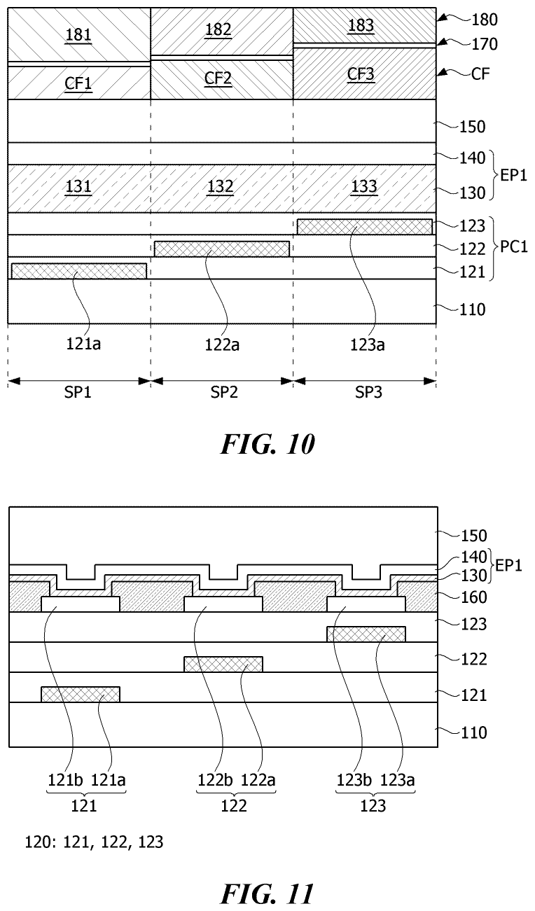

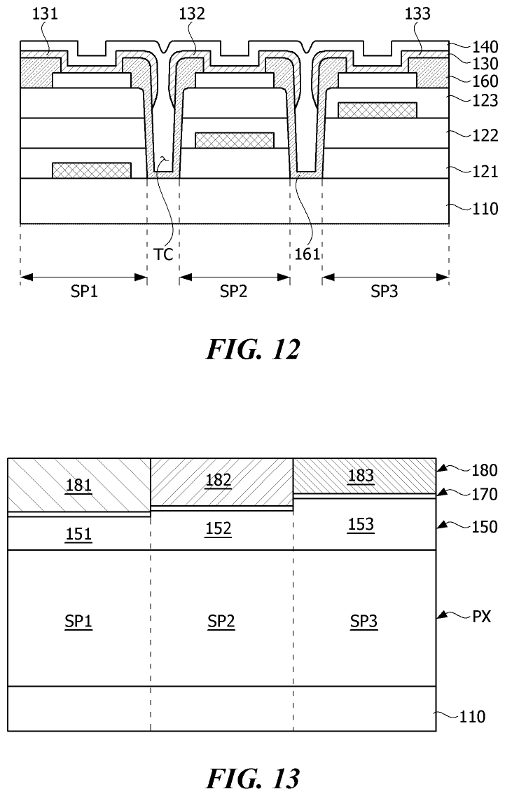

FIG. 10 is a view illustrating a display panel according to a second embodiment of the present disclosure. FIG. 11 is a view illustrating a display panel according to a third embodiment of the present disclosure. FIG. 12 is a view illustrating a display panel according to a fourth embodiment of the present disclosure.

Referring to FIG. 10, a plurality of sub-pixels SP1, SP2, and SP3 and an encapsulation layer 150 may be stacked on a substrate 110. Each of the plurality of sub-pixels SP1, SP2, and SP3 may include a circuit layer PC1 and a light-emitting element layer EP1.

The circuit layer PC1 includes pixel circuits which drive light-emitting elements of the sub-pixels SP1, SP2, and SP3 according to pixel data of an input image. The circuit layer PC1 may further include a gate driving circuit which supplies a gate signal to the pixel circuits. The pixel circuit may include a driving transistor which supplies a current to the light-emitting elements according to a gate-source voltage, a switching transistor which applies a data voltage of the pixel data to a gate or source of the driving transistor, a storage capacitor which maintains the gate-source voltage of the driving transistor, and a plurality of insulating layers which insulate metal patterns of the circuit elements.

The light-emitting element layer EP1 includes a light-emitting element disposed in each of the sub-pixels SP1, SP2, and SP3 and driven by the pixel circuit. The light-emitting element layer EP1 may be a white light-emitting element which is disposed in the sub-pixels SP1, SP2, and SP3 in common and generates white light.

In another embodiment, a red light-emitting element which generates red light may be disposed in a first sub-pixel SP1, and a green light-emitting element which generates green light may be disposed in a second sub-pixel SP2, and a blue light-emitting element which generates blue light may be disposed in a third sub-pixel SP3.

The light-emitting element may be implemented as an organic light-emitting element or an inorganic light-emitting element. For example, the light-emitting element may be implemented as an organic light-emitting diode (OLED) or an inorganic LED.

A first electrode 120 may be an anode of the light-emitting element separated for each sub-pixel. A second electrode 140 may be a common electrode shared by the sub-pixel. The second electrode 140 may be a cathode of the light-emitting element.

The encapsulation layer 150 may cover the light-emitting element layer EP1 to seal the circuit layer PC1 and the light-emitting element layer EP1. The encapsulation layer 150 may have a multi-insulating film structure in which organic films and inorganic films are alternately stacked. The inorganic film blocks the penetration of moisture or oxygen. The organic film planarizes a surface of the inorganic film. When the organic film and the inorganic film are stacked in multiple layers, since a movement path of the moisture or oxygen is longer compared to a single layer, the penetration of the moisture and oxygen which affects the light-emitting element layer EP1 may be effectively blocked.

The first electrode 120 may also serve as a reflective layer to increase light efficiency, and the second electrode 140 may be implemented as a transparent or translucent electrode. In a top-emission type display panel, distances between the first electrode 120 and the second electrode 140 may be set differently for colors of the sub-pixels SP1, SP2, and SP3 to acquire a microcavity effect. When a microcavity is used, since constructive interference occurs in light reflected between the electrodes 120 and 140 and thus an amplitude of a wavelength of the light increases, an amount of light emitted to the outside in a top-emission type display panel may be increased.

A color filter CF, an alignment film 170, and a reflective layer 180 may have the same structure as described above.

Referring to FIG. 11, a first electrode 120 may include driving electrodes 121b, 122b, and 123b disposed under a light-emitting element layer EP1, and reflective electrodes 121a, 122a, and 123a respectively disposed under the driving electrodes 121b, 122b, and 123b. The driving electrodes 121b, 122b, and 123b may serve to apply a pixel driving voltage to the light-emitting element layer EP1. The driving electrodes 121b, 122b, and 123b may be manufactured as transparent electrodes or translucent electrodes.

The reflective electrodes 121a, 122a, and 123a may be disposed to be spaced apart from a second electrode 140 at appropriate positions for a microcavity effect. The reflective electrodes 121a, 122a, and 123a may be disposed between a plurality of insulating layers 121, 122, and 123 for sub-pixels SP1, SP2, and SP3, respectively. The reflective electrodes 121a, 122a, and 123a may be made of a highly reflective metal such as silver (Ag) or aluminum (Al). The driving electrodes 121b, 122b, and 123b and the reflective electrodes 121a, 122a, and 123a may be electrically connected to each other by through electrodes (not shown).

Banks 160 may be disposed between the plurality of driving electrodes 121b, 122b, and 123b. The banks 160 may partition the plurality of sub-pixels SP1, SP2, and SP3. The light-emitting element layer EP1 may be continuously formed on the plurality of driving electrodes 121b, 122b, and 123b and the banks 160.

Referring to FIG. 12, trenches TC may be formed between a plurality of sub-pixels SP1, SP2, and SP3. Accordingly, a light-emitting element layer EP1 is cut by the trenches TC, thus improving a leakage current LLC. The embodiment illustrates that the trenches TC are filled with banks 160, but is not necessarily limited thereto.

A depth of the trench TC is not specifically limited. For example, the trench TC may be formed with a depth corresponding to a thickness of the bank 160. Alternatively, the trench TC may be formed only to partial regions of the insulating layers 121, 122, and 123.

FIG. 13 is a view illustrating a display panel according to a fifth embodiment of the present disclosure.

Referring to FIG. 13, a display panel according to the embodiment may include a substrate 110, a pixel PX including a plurality of sub-pixels SP1, SP2, and SP3 disposed on the substrate 110, and a reflective layer 180 disposed on the plurality of sub-pixels SP1, SP2, and SP3.

The substrate 110 may be manufactured based on glass, plastic, and a silicon wafer. The substrate 110 may be interpreted as a backplane.

A structure of a plurality of pixels PX is not specifically limited. For example, the plurality of pixels PX may include organic light-emitting diode (OLED) elements or inorganic light-emitting diode (LED) elements. The inorganic LED elements may serve as sub-pixels as each of small micro-sized LEDs emits light.

Each of the plurality of pixels may include a first sub-pixel SP1, a second sub-pixel SP2, and a third sub-pixel SP3 to implement colors. The first sub-pixel SP1, the second sub-pixel SP2, and the third sub-pixel SP3 may output light in different wavelength bands. For example, the first sub-pixel SP1 may output light in a red wavelength band, the second sub-pixel SP2 may output light in a green wavelength band, and the third sub-pixel SP3 may output light in a blue wavelength band. Each sub-pixel may include a light-emitting element layer and a circuit layer which drives the light-emitting element layer.

However, the present disclosure is not necessarily limited thereto, and the first sub-pixel SP1, the second sub-pixel SP2, and the third sub-pixel SP3 may all output light in the same wavelength band. For example, the first sub-pixel SP1, the second sub-pixel SP2, and the third sub-pixel SP3 may all output light in a white wavelength band. To this end, each of the sub-pixels SP1, SP2, and SP3 may have a structure in which a red light-emitting layer, a green light-emitting layer, and a blue light-emitting layer are stacked.

An encapsulation layer 150 may cover the pixel to seal a circuit layer PC1 and a light-emitting element layer EP1. The encapsulation layer 150 may have a multi-insulating film structure in which organic films and inorganic films are alternately stacked. The inorganic film blocks the penetration of moisture or oxygen. The organic film planarizes a surface of the inorganic film. When the organic film and the inorganic film are stacked in multiple layers, since a movement path of the moisture or oxygen is longer compared to a single layer, the penetration of the moisture and oxygen which affects the light-emitting element layer EP1 may be effectively blocked.

The encapsulation layer 150 may include a first encapsulation portion to a third encapsulation portion 151, 152, and 153 having different thicknesses. For example, the first encapsulation portion 151 may be manufactured with a thickness smaller than the thickness of the second encapsulation portion 152, and second encapsulation portion 152 may be manufactured with a thickness smaller than the thickness of the third encapsulation portion 153. Accordingly, the third encapsulation portion 153 may be manufactured with the greatest thickness and the first encapsulation portion 151 may be manufactured with the smallest thickness. The first encapsulation portion to the third encapsulation portion 151, 152, and 153 may be manufactured with the same thickness and then the thickness may be adjusted through a separate etching process. Various semiconductor etching processes may be applied to the etching process.

An alignment film 170 may be formed on the first encapsulation portion to the third encapsulation portion 151, 152, and 153. The alignment film 170 may be rubbed in one direction. Accordingly, an alignment angle of a liquid crystal formed on the alignment film 170 may be set according to an aligning direction.

The reflective layer 180 may include a first reflective portion 181 disposed on the first encapsulation portion 151, a second reflective portion 182 disposed on the second encapsulation portion 152, and a third reflective portion 183 disposed on the third encapsulation portion 153.

According to the embodiment, the reflective layer 180 may be manufactured with cholesteric liquid crystals CLC. When the cholesteric liquid crystals are applied on the first encapsulation portion to the third encapsulation portion 151, 152, and 153 manufactured with the different thicknesses, the first reflective portion 181 having a first thickness may be formed on the first sub-pixel SP1, the second reflective portion 182 having a second thickness may be formed on the second sub-pixel SP2, and the third reflective portion 183 having a third thickness may be formed on the third sub-pixel SP3.

When upper surfaces of the cholesteric liquid crystal are formed to be the same, the first reflective portion to the third reflective portions 181, 182, and 183 may be manufactured with different thicknesses. The first reflective portion 181 formed on the first encapsulation portion 151 which is disposed to be the lowest may be thicker than the second reflective portion 182 formed on the second encapsulation portion 152, and the second reflective portion 182 may be thicker than the third reflective portion 183.

As a result, in the first reflective portion 181 which is manufactured to be the thickest, the cholesteric liquid crystals may grow in a helical shape and have a pitch which reflects light in the red wavelength band. Further, in the second reflective portion 182 which is manufactured with a thickness smaller than that of the first reflective portion 181, the cholesteric liquid crystals may grow in a helical shape and have a pitch which reflects light in the green wavelength band. In addition, in the third reflective portion 183 manufactured with the smallest thickness, the cholesteric liquid crystals may grow in a helical shape and have a pitch which reflects light in the blue wavelength band.

Since the wavelength band in which the cholesteric liquid crystals perform reflection varies according to the pitches, the thickness of the encapsulation layer 150 may be adjusted differently for region to reflect light emitted from the pixel.

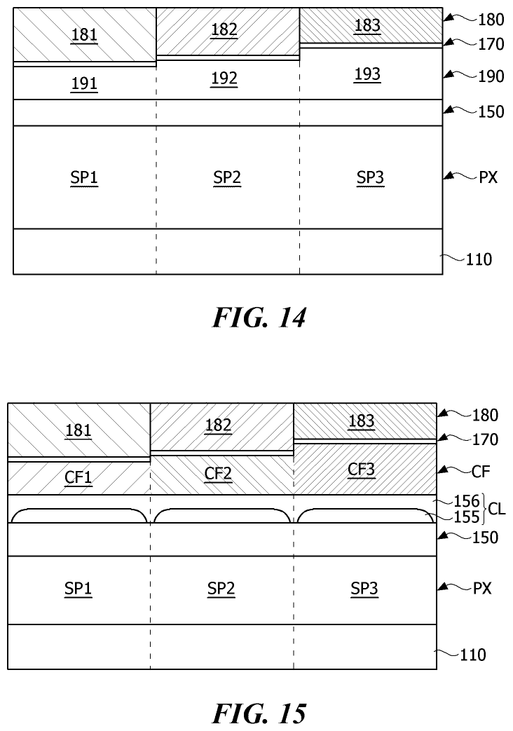

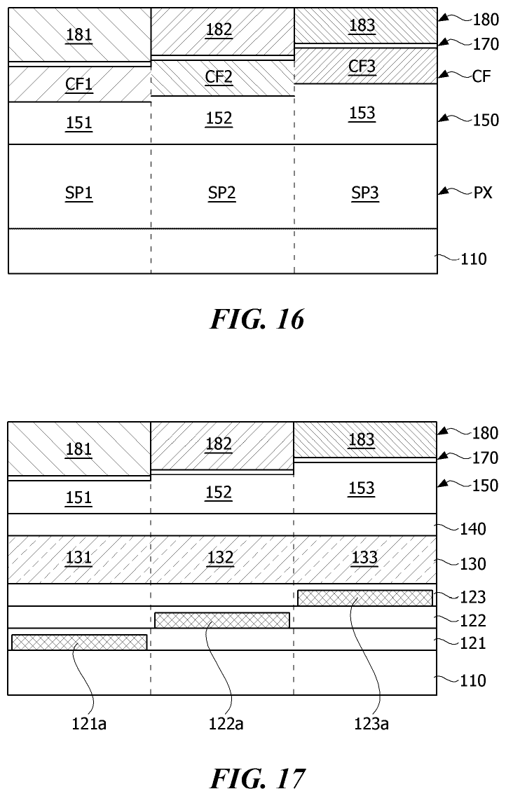

FIG. 14 is a view illustrating a display panel according to a sixth embodiment of the present disclosure. FIG. 15 is a view illustrating a display panel according to a seventh embodiment of the present disclosure. FIG. 16 is a view illustrating a display panel according to an eighth embodiment of the present disclosure. FIG. 17 is a view illustrating a display panel according to a ninth embodiment of the present disclosure.

Referring to FIG. 14, a separate optical layer 190 may be further disposed on an encapsulation layer 150. The optical layer 190 may be a layer of various light-transmissive materials used or usable in the display panel such as a bank or various organic and inorganic material layers. The optical layer 190 may include a first step portion 191, a second step portion 192, and a third step portion 193 having different thicknesses.

According to this configuration, the encapsulation layer 150 may be manufactured flat to protect a pixel, and the optical layer 190 may be additionally formed on the encapsulation layer 150 to form a step.

Referring to FIG. 15, a light concentrating layer CL may be further disposed between a color filter CF and an encapsulation layer 150. At least one high refractive index layer 155 and one low refractive index layer 156 may be stacked in the light concentrating layer CL. In this case, one of the high refractive index layer 155 and the low refractive index layer 156 may have a convex shape such as a prism, a cone shape, or a dome shape. Since light emitted from sub-pixels SP1, SP2, and SP3 is concentrated by the light concentrating layer, the extraction efficiency of light may be improved.

Referring to FIG. 16, after forming a step in an encapsulation layer 150, a color filter CF may be manufactured on the encapsulation layer 150. Since the step is formed by the encapsulation layer 150, the color filter CF may be manufactured with the same thickness. Accordingly, conventional performance of the color filter CF may be maintained as it is.

Referring to FIG. 17, a plurality of sub-pixels SP1, SP2, and SP3 and an encapsulation layer 150 may be stacked on a substrate 110. The plurality of sub-pixels SP1, SP2, and SP3 may include a plurality of circuit layers PC1 and a light-emitting element layer EP1.

The light-emitting element layer EP1 includes light-emitting elements respectively disposed in the sub-pixels SP1, SP2, and SP3 and driven by the pixel circuits. The light-emitting element layer EP1 may be a white light-emitting element which is disposed in the sub-pixels SP1, SP2, and SP3 in common and generates white light.

In another embodiment, a red light-emitting element which generates red light may be disposed in a red sub-pixel SP1, and a green light-emitting element which generates green light may be disposed in a green sub-pixel SP2, and a blue light-emitting element which generates blue light may be disposed in a blue sub-pixel SP3.

The light-emitting element may be implemented as an organic light-emitting element or an inorganic light-emitting element. For example, the light-emitting element may be implemented as an organic light-emitting diode (OLED) or an inorganic LED.

A first electrode 120 may be an anode of the light-emitting element separated for each sub-pixel. A second electrode 140 may be a common electrode shared by the sub-pixel. The second electrode 140 may be a cathode of the light-emitting element.

The encapsulation layer 150 may cover the light-emitting element layer EP1 to seal the circuit layer PC1 and the light-emitting element layer EP1. The encapsulation layer 150 may have a multi-insulating film structure in which organic films and inorganic films are alternately stacked. The inorganic film blocks the penetration of moisture or oxygen. The organic film planarizes a surface of the inorganic film. When the organic film and the inorganic film are stacked in multiple layers, since a movement path of the moisture or oxygen is longer compared to a single layer, the penetration of the moisture and oxygen which affects the light-emitting element layer EP1 may be effectively blocked.

The first electrode 120 may also serve as a reflective layer to increase light efficiency, and the second electrode 140 may be implemented as a transparent or translucent electrode. In a top-emission type display panel, distances between the first electrode 120 and the second electrode 140 may be set differently for colors of the sub-pixels SP1, SP2, and SP3 to acquire a microcavity effect. When a microcavity is used, since constructive interference occurs in light reflected between the electrodes 120 and 140 and thus an amplitude of a wavelength of the light increases, an amount of light emitted to the outside in a top-emission type display panel may be increased.

The encapsulation layer 150, an alignment film 170, and a reflective layer 180 may have the same structure as described above.

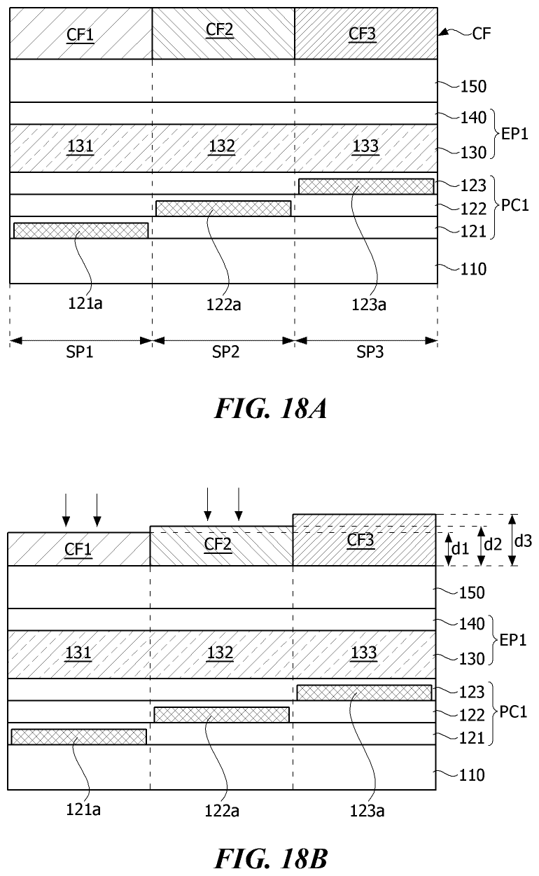

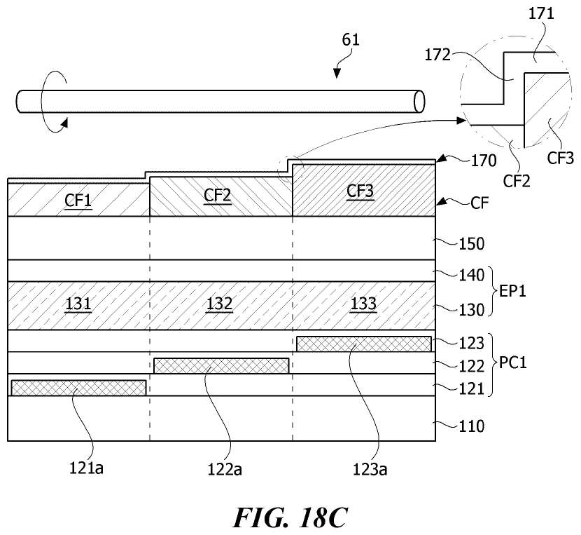

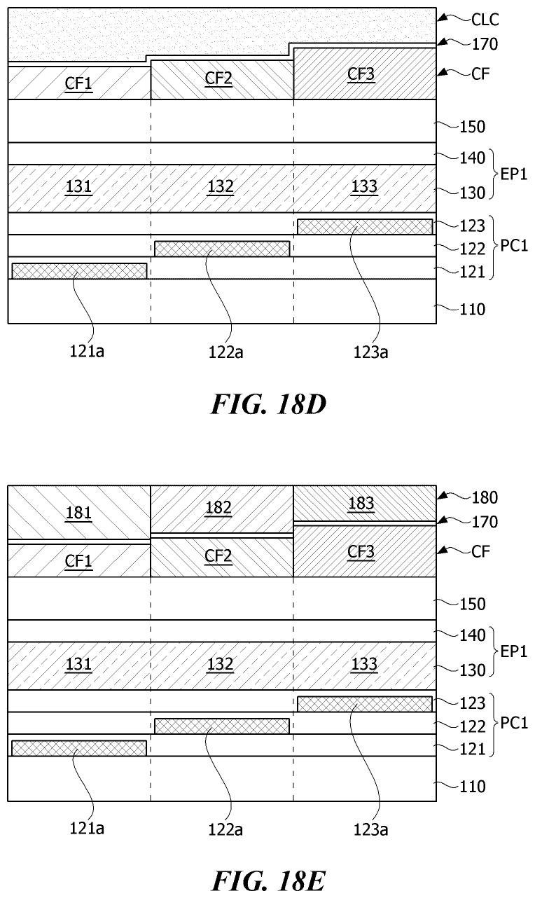

FIGS. 18A to 18E are views illustrating a process of manufacturing a display panel according to one embodiment of the present disclosure.

Referring to FIG. 18A, a plurality of first electrodes 160 may be formed on a substrate 110. The plurality of first electrodes 160 may be disposed with different heights depending on types of sub-pixel SP1, SP2, and SP3. The plurality of first electrodes 160 may be selectively disposed on a plurality of insulating layers 121, 122, and 123.

A light-emitting element layer EP1 may be disposed on the first electrodes 160, and a second electrode 140 and an encapsulation layer 150 may be disposed on the light-emitting element layer EP1.

A color filter CF including a first filter CF1, a second filter CF2, and a third filter CF3 may be formed on the encapsulation layer 150. In this case, thicknesses of the first filter CF1, the second filter CF2, and the third filter CF3 may be the same.

Referring to FIG. 18B, the first filter CF1 and the second filter CF2 may be selectively etched. The third filter CF3 may also be etched to have a required thickness. Various semiconductor etching methods may be applied as the method of etching the color filter CF. For example, a plasma etching method or a dry or wet etching method using a mask may be applied.

The etching may be performed so that a thickness d1 of the first filter CF1 is smaller than a thickness d2 of the second filter CF2, and the etching may be performed so that the thickness d2 of the second filter CF2 is smaller than a thickness d3 of the third filter CF3.

Referring to FIG. 18C, an alignment film 170 may be applied and rubbed on the first to third filters CF1, CF2, and CF3 having different thicknesses. In this case, since the first to third filters CF1, CF2, and CF3 have the different thicknesses, the alignment film 170 applied thereon may include first alignment regions 171 disposed on the first to third filters CF1, CF2, and CF3 and second alignment regions 172 disposed on a side surface of the second filter CF2 and a side surface of the third filter CF3. The alignment film 170 may be rubbed in one direction by a rubbing member 61. In this case, not only the first alignment regions 171 but also the second alignment regions 172 of the alignment film 170 may be rubbed.

Referring to FIG. 18D, cholesteric liquid crystals CLC may be applied on the alignment film 170. The cholesteric liquid crystals CLC may be applied to have flat upper surfaces. Accordingly, the cholesteric liquid crystals disposed on the relatively thin first filter CF1 may be relatively thick. On the other hand, the cholesteric liquid crystals disposed on the thick third filter CF3 may be relatively thin.

Referring to FIG. 18E, the process may be completed by curing the cholesteric liquid crystals CLC. A pitch of a helix formed by cholesteric liquid crystal molecules in the first reflective layer 181 may be 365 nm to 520 nm. A pitch of a helix formed by cholesteric liquid crystal molecules in the second reflective layer 182 may be 290 nm to 380 nm. A pitch of a helix formed by cholesteric liquid crystal molecules in the third reflective layer 183 may be 265 nm to 330 nm.

The first reflective portion 181 may transmit right-circularly polarized red light and reflect left-circularly polarized red light among red light emitted by the first filter CF1. Since the reflected light is reflected by a reflective plate or the substrate 110 disposed at a lower portion of the pixel, a polarization direction may be changed. Accordingly, the reflected red light may pass through the first filter CF1 and the first reflective portion 181 again and may be emitted to the outside.

The second reflective portion 182 may transmit right-circularly polarized light and reflect left-circularly polarized light among green light emitted from the second filter CF2. Since the reflected light is reflected by the reflective plate or the substrate 110 disposed at the lower portion of the pixel, a polarization direction is changed and thus the reflected light may pass through the second reflective portion 182.

The third reflective portion 183 may transmit left-circularly polarized light and reflect right-circularly polarized light among blue light emitted from the third filter CF3. Since the reflected light is reflected by the reflective plate or the substrate 110 disposed at the lower portion of the pixel, a polarization direction is changed, and thus the reflected light may pass through the third reflective portion 183.

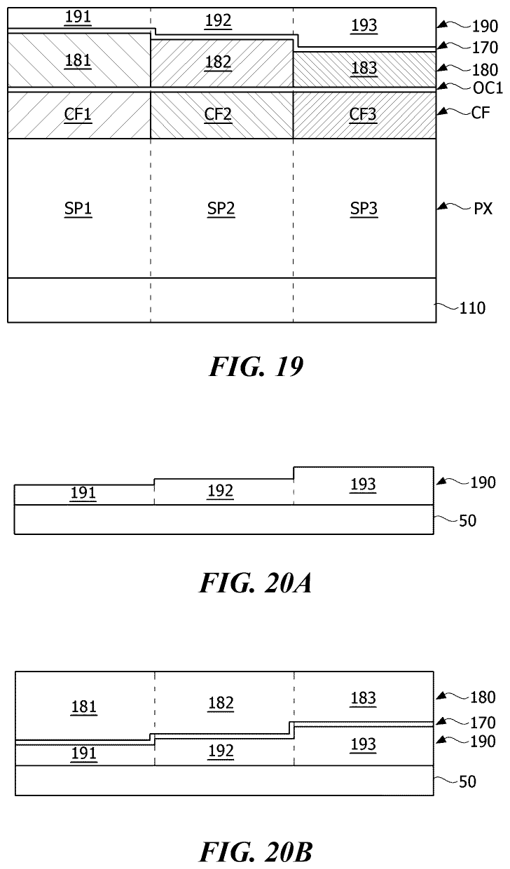

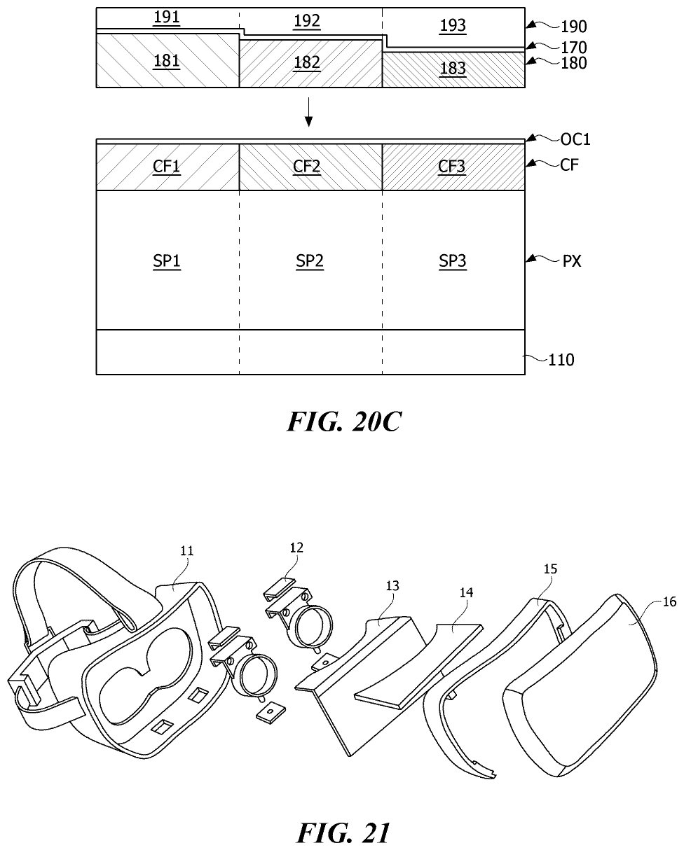

FIG. 19 is a view illustrating a display panel according to a tenth embodiment of the present disclosure. FIGS. 20A to 20C are views illustrating a process of manufacturing a display panel according to one embodiment of the present disclosure.

Referring to FIG. 19, a display panel may include a plurality of sub-pixels SP1, SP2, and SP3 disposed on a substrate 110, a color filter CF disposed on the plurality of sub-pixels SP1, SP2, and SP3, a reflective layer 180 disposed on the color filter CF, and an optical layer 190 disposed on the reflective layer 180.

The color filter CF may include a first filter CF1, a second filter CF2, and a third filter CF3, and thicknesses of the first filter CF1, the second filter CF2, and the third filter CF3 may be the same. The first filter CF1 may be a red filter, the second filter CF2 may be a green filter, and the third filter CF3 may be a blue filter.

The reflective layer 180 may include a first reflective portion 181 disposed on the first filter CF1, a second reflective portion 182 disposed on the second filter CF2, and a third reflective portion 183 disposed on the third filter CF3. The first reflective portion 181 may be manufactured to be thicker than the second reflective portion 182, and the second reflective portion 182 may be manufactured to be thicker than the third reflective portion 183.

According to the embodiment, the reflective layer 180 may be manufactured with cholesteric liquid crystals CLC. Accordingly, the first reflective portion 181 which is formed to be the thickest may transmit right-circularly polarized light and reflect left-circularly polarized light among red light emitted from the first filter CF1. Since the reflected light may be reflected by a reflective plate or the substrate 110 disposed at a lower portion of a pixel, a polarization direction may be changed. Accordingly, the reflected red light may pass through the first filter CF1 and the first reflective portion 181 again to be emitted to the outside. The extraction efficiency of light emitted from the display panel may be improved in green light emitted from the second sub-pixel SP2 and blue light emitted from the third sub-pixel SP3 according to the same principle.

The reflective layer 180 may be attached to the color filter CF by an adhesive layer OC1. According to the embodiment, the reflective layer 180 may be manufactured separately and attached to the color filter CF. According to this configuration, all of thicknesses of the color filters 160 may be manufactured to be the same.

The optical layer 190 may be disposed on the reflective layer 180. The optical layer 190 may include a first step portion 191 disposed on the first reflective portion 181, a second step portion 192 disposed on the second reflective portion 182, and a third step portion 193 disposed on the third reflective portion 183.

The reflective layer 180 may be manufactured so that the first reflective portion 181 is the thickest and the third reflective portion 183 is the thinnest. On the other hand, the optical layer 190 may be manufactured so that the first step portion 191 is the thinnest and the third step portion 193 is the thickest. Accordingly, the sum of the thicknesses of the first reflective portion 181 and the first step portion 191 may be equal to the sum of the thicknesses of the third reflective portion 183 and the third step portion 193.

Referring to FIG. 20A, an optical layer 190 may be formed on a manufacturing substrate 50. The optical layer 190 may be formed using an encapsulation layer, a bank, or other transparent optical layers. The optical layer 190 may be formed with the same thickness and then a first step portion to a third step portion 191, 192, and 193 may be formed by etching.

Referring to FIG. 20B, after applying an alignment film 170 on the optical layer 190, a reflective layer 180 may be formed by applying a cholesteric liquid crystal layer. Since thicknesses of the first to third step portions 191, 192, and 193 are different, pitches of the cholesteric liquid crystal molecules formed thereon may also be different.

Referring to FIG. 20C, after removing the manufacturing substrate 50, the reflective layer 180 may be attached to a color filter CF. According to this configuration, since the color filter CF may be manufactured with the same thickness, the performance of the color filter CF may be maintained.

FIG. 21 is an exploded perspective view illustrating a personal immersive device according to one embodiment of the present disclosure.

Referring to FIG. 21, the personal immersive device includes a lens module 12, a display module 13, a main board 14, a head gear 11, a side frame 15, a front cover 16, and the like.

The display module 13 may include a display panel driving circuit for driving each of two display panels and display an input image received from the main board 14. The display panels may be classified as a first display panel visible to a user's left eye and a second display panel visible to a user's right eye. The display module may display image data input from the main board on display panels. The image data may be two-dimensional (2D)/three-dimensional (3D) image data which implements a video image of virtual reality (VR) or augmented reality (AR). The display module 13 may display various types of information input from the main board in a form of texts, symbols, or the like.

The lens module 12 may include an ultra-wide-angle lens, that is, a pair of fisheye lenses (LENS) to expand an angle of view of user's left and right eyes. The pair of fisheye lenses (LENS) may include a left eye lens disposed in front of the first display panel and a right eye lens disposed in front of the second display panel.

The main board 14 may include a processor which executes virtual reality software and supplies a left-eye image and a right-eye image to the display module 13. Further, the main board 14 may further include an interface module, a sensor module, and the like connected to an external device. The interface module may be connected to an external device through an interface such as a universal serial bus (USB), a high-definition multimedia interface (HDMI), or the like. The sensor module may include various sensors such as a gyro sensor, an acceleration sensor, and the like. The processor of the main board 14 may correct the left-eye and right-eye image data in response to an output signal of the sensor module and transmit the left-eye data and the right-eye image data of the input image received through the interface module to the display module 13. The processor may generate a left-eye image and a right-eye image which match the resolution of the display panel based on a depth information analysis result of a 2D image and then transmit the left-eye image and the right-eye image to the display module 13.

The head gear 11 may include a back cover which exposes the fisheye lenses (LENS) and a band connected to the back cover. The back cover, the side frame 15, and the front cover 16 of the head gear 11 may be assembled to secure an inner space where components of the personal immersive device are disposed and to protect the components. The components may include the lens module 12, the display module 13, and the main board 14. The band may be connected to the back cover. A user may wear the personal immersive device on a user's head with the band. When the personal immersive device is worn on the user's head, the user may view different display panels with left and right eyes through the fisheye lenses (LENS).

The side frame 15 may be fixed between the head gear 11 and the front cover 16 to secure a gap in the inner space where the lens module 12, the display module 13, and the main board 14 are disposed. The front cover 16 may be disposed on a front surface of the personal immersive device.

The personal immersive device of the present disclosure may be implemented as a head mounted display (HMD) structure, but is not limited thereto. For example, the present disclosure may be designed as an eyeglasses-type display (EGD) of a glasses structure, a face mounted display (FMD) worn on the face, or the like.

A display panel according to the present specification can simultaneously serve as a polarizer and a light concentrating layer using a cholesteric liquid crystal reflective layer. Accordingly, since a polarization-based optical system can be used, it is possible to minimize a device and the brightness can be improved. As a result, low-power driving can be possible.

Further, since a reflective layer can simultaneously serve as conventional polarizer and light concentrating layer, and thus a conventional stress-sensitive circular polarizer can be omitted, the reliability of a panel can be improved and a panel manufacturing process can be simplified.

The effects according to the present specification are not limited to the above-mentioned effects, and other effects which are not mentioned can be clearly understood by those skilled in the art from the description.

Since the content of the specification disclosed in the technical problems to be solved, technical solutions, and the effects described above do not specify essential features of the claims, the scope of the claims is not limited by the disclosure.

Although the embodiments of the present disclosure have been described in more detail with reference to the accompanying drawings, the present disclosure is not necessarily limited to these embodiments, and may be variously modified without departing from the technical spirit of the present disclosure. Accordingly, the embodiments disclosed in the present disclosure are not intended to limit the technical spirit of the present disclosure, but to describe the technical spirit of the present disclosure, and the scope of the technical spirit of the present disclosure is not limited by these embodiments. Accordingly, the above-described embodiments should be understood in all respects as illustrative and not restrictive. The scope of the present disclosure should be interpreted that all technical ideas within the equivalent range are included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a substrate;
a plurality of pixels disposed on the substrate, each of the plurality of pixels including a first sub-pixel, a second sub-pixel, and a third sub-pixel; and
a reflective layer including a first reflective portion disposed on the first sub-pixel, a second reflective portion disposed on the second sub-pixel, and a third reflective portion disposed on the third sub-pixel,
wherein a thickness of the first reflective portion, a thickness of the second reflective portion, and a thickness of the third reflective portion are each different.

2. The display panel of claim 1, wherein the first reflective portion is thicker than the second reflective portion, and
the second reflective portion is thicker than the third reflective portion.

3. The display panel of claim 2, wherein the reflective layer includes cholesteric liquid crystals, and
a pitch of the cholesteric liquid crystals in each of the first reflective portion, the second reflective portion, and the third reflective portion are different.

4. The display panel of claim 3, wherein the first reflective portion is configured to selectively transmit and reflect red light corresponding to the pitch of the cholesteric liquid crystal in the first reflective portion,
the second reflective portion is configured to selectively transmit and reflect green light corresponding to the pitch of the cholesteric liquid crystal in the second reflective portion, and
the third reflective portion is configured to selectively transmit and reflect blue light corresponding to the pitch of the cholesteric liquid crystal in the third reflective portion.

5. The display panel of claim 1, further comprising a color filter disposed between the plurality of pixels and the reflective layer,
wherein the color filter includes a first filter disposed between the first sub-pixel and the first reflective portion, a second filter disposed between the second sub-pixel and the second reflective portion, and a third filter disposed between the third sub-pixel and the third reflective portion.

6. The display panel of claim 5, wherein a thickness of the first filter is less than a thickness of the second filter, and
the thickness of the second filter is less than a thickness of the third filter.

7. The display panel of claim 1, further comprising an encapsulation layer disposed between the plurality of pixels and the reflective layer,
wherein the encapsulation layer includes a first encapsulation portion disposed between the first sub-pixel and the first reflective portion, a second encapsulation portion disposed between the second sub-pixel and the second reflective portion, and a third encapsulation portion disposed between the third sub-pixel and the third reflective portion,
a thickness of the second encapsulation portion is greater than a thickness of the first encapsulation portion, and
a thickness of the third encapsulation portion is greater than the thickness of the second encapsulation portion.

8. The display panel of claim 6, further comprising an alignment film disposed between the reflective layer and the color filter.

9. The display panel of claim 8, wherein the alignment film includes:
first alignment regions disposed on the first filter, the second filter, and the third filter; and
second alignment regions disposed on a side surface of the second filter and a side surface of the third filter.

10. The display panel of claim 1, further comprising a light concentrating layer disposed between the plurality of pixels and the reflective layer,
wherein the light concentrating layer includes:
high refractive index layers disposed on the first sub-pixel, the second sub-pixel, and the third sub-pixel; and
a low refractive index layer disposed on the high refractive index layers.

11. The display panel of claim 1, wherein each of the first sub-pixel, the second sub-pixel, and the third sub-pixel includes a first electrode, a light-emitting element disposed on the first electrode, and a second electrode disposed on the light-emitting element.

12. The display panel of claim 11, wherein light reflected by the reflective layer is reflected toward the reflective layer by the first electrode.

13. A personal immersive device comprising:
a display panel; and
a lens disposed on the display panel,
wherein the display panel includes:
a substrate;
a plurality of pixels disposed on the substrate, each of the plurality of pixels including a first sub-pixel, a second sub-pixel, and a third sub-pixel; and
a reflective layer including a first reflective portion disposed on the first sub-pixel, a second reflective portion disposed on the second sub-pixel, and a third reflective portion disposed on the third sub-pixel, and
wherein a thickness of the first reflective portion, a thickness of the second reflective portion, and a thickness of the third reflective portion are each different.

14. The personal immersive device of claim 13, wherein the first reflective portion is thicker than the second reflective portion, and
the second reflective portion is thicker than the third reflective portion.

15. The personal immersive device of claim 14, wherein the reflective layer includes cholesteric liquid crystals, and
a pitch of the cholesteric liquid crystals in each of the first reflective portion, the second reflective portion, and the third reflective portion are different.

16. The personal immersive device of claim 13, further comprising a color filter disposed between the plurality of pixels and the reflective layer,
wherein the color filter includes a first filter disposed between the first sub-pixel and the first reflective portion, a second filter disposed between the second sub-pixel and the second reflective portion, and a third filter disposed between the third sub-pixel and the third reflective portion.

17. The personal immersive device of claim 16, wherein a thickness of the first filter is less than a thickness of the second filter, and
the thickness of the second filter is less than a thickness of the third filter.

18. A display panel comprising:
a substrate;
a plurality of pixels disposed on the substrate, each of the plurality of pixels including a first sub-pixel, a second sub-pixel, and a third sub-pixel;
a color filter including a red filter disposed on the first sub-pixel, a green filter disposed on the second sub-pixel, and a blue filter disposed on the third sub-pixel; and
a cholesteric liquid crystal layer including a first cholesteric liquid crystal portion disposed on the red filter, a second cholesteric liquid crystal portion disposed on the green filter, and a third cholesteric liquid crystal portion disposed on the blue filter,
wherein a thickness of the first cholesteric liquid crystal portion is greater than a thickness of the second cholesteric liquid crystal portion, and the thickness of the second cholesteric liquid crystal portion is greater than a thickness of the third cholesteric liquid crystal portion.

19. The display panel of claim 18, wherein a thickness of the red filter is less than a thickness of the green filter, and the thickness of the green filter is less than a thickness of the blue filter.

20. The display panel of claim 18, further comprising a reflective plate disposed between the substrate and the plurality of pixels.
